(19) United States
(12) Patent Application Publication
(10) Pub. No.: US 2013/0329387 A1
(43) Pub. Date: Dec. 12, 2013

(54) CIRCUIT BOARD MOUNTING APPARATUS

(71) Applicants: Chien-Chung HUANG, New Taipei (TW); Zheng-Heng SUN, New Taipei (TW)

(72) Inventors: Chien-Chung HUANG, New Taipei (TW); Zheng-Heng SUN, New Taipei (TW)

(21) Appl. No.: 13/678,565

(22) Filed: Nov. 16, 2012

(30) Foreign Application Priority Data
Jun. 12, 2012 (CN) 2012101915225

(51) Int. Cl. H05K 3/30

(52) U.S. Cl. CPC H05K 3/301
USPC 361/767

(57) ABSTRACT

A circuit board mounting apparatus includes a circuit board, a chassis, and two mounting members. Two slots are defined in a front side of the circuit board. The chassis includes a side plate. The mounting members are fixed to the side plate and respectively connected to the slots of the circuit board. Each of the mounting members includes a hook locked to the circuit board, to perpendicularly fix the circuit board to the side plate.

### BACKGROUND

1. Technical Field

The present disclosure relates to a circuit board mounting apparatus.

2. Description of Related Art

In electronic devices, circuit boards may be mounted inside the devices with a number of screws extended through the circuit board and engaged in a number of posts on a bottom wall of the chassis of the devices. However, manually fastening many screws in the chassis can be difficult and inconvenient because of the limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a circuit board mounting apparatus, wherein the circuit board mounting apparatus includes two mounting members.

FIG. 2 is an enlarged view of one of the mounting members of FIG. 1 from another perspective.

FIG. 3 is an assembled, isometric view of FIG. 1.

FIG. 4 is similar to FIG. 3, but viewed from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

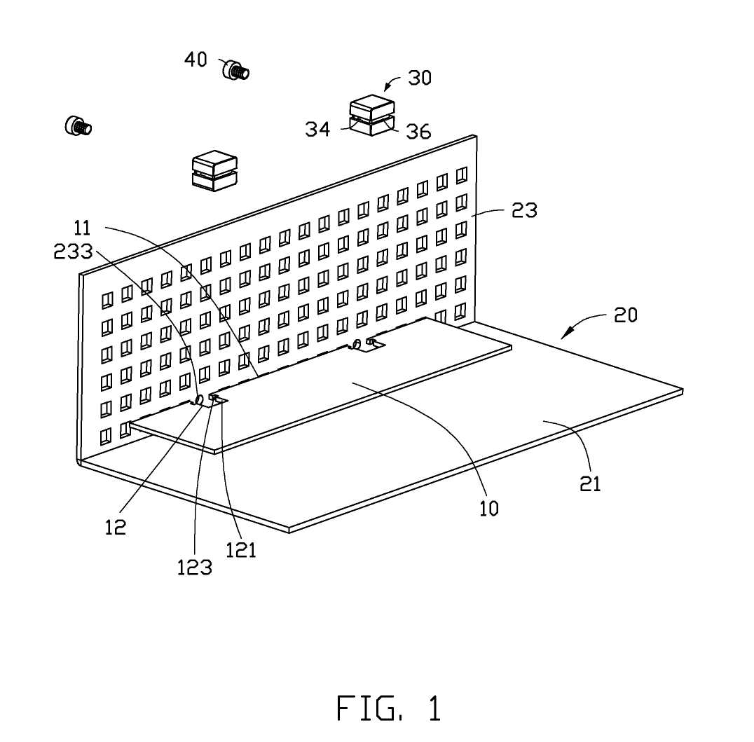

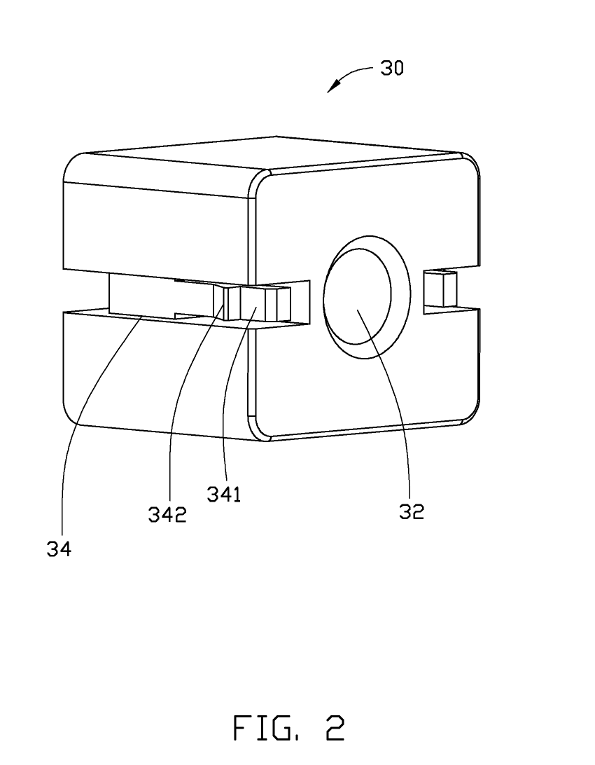

Referring to FIGS. 1 and 2, a circuit board mounting apparatus includes a circuit board 10, a chassis 20, two mounting members 30, and two fasteners. In the embodiment, the fasteners are screws 40.

Two slots 12 are defined in a front side 11 of the circuit board 10. The circuit board 10 forms two sidewalls 121 bounding opposite sides of each slot 12. A notch 123 is defined in each sidewall 121 adjacent to a front end of the sidewall 121.

The chassis 20 includes a bottom plate 21 and a side plate 23 extending up from the front side of the bottom plate 21. Two spaced holes 233 are defined in the side plate 23 adjacent to the bottom plate 21.

A horizontally extending fixing hole 32 is defined in the front end of each mounting member 30. Two first recesses 34 are respectively defined in opposite sides of each mounting member 30, extending horizontally through the front end and the rear end of the mounting member 30. A second recess 36 is defined in the rear end of each mounting member 30, with opposite ends of the second recess 36 communicating with the corresponding first recesses 34. A resilient arm 341 slantingly extends forward and outward from a sidewall of each first recess 34. A hook 342 protrudes from an outer side of each resilient arm 341 adjacent to the front end of the resilient arm 341.

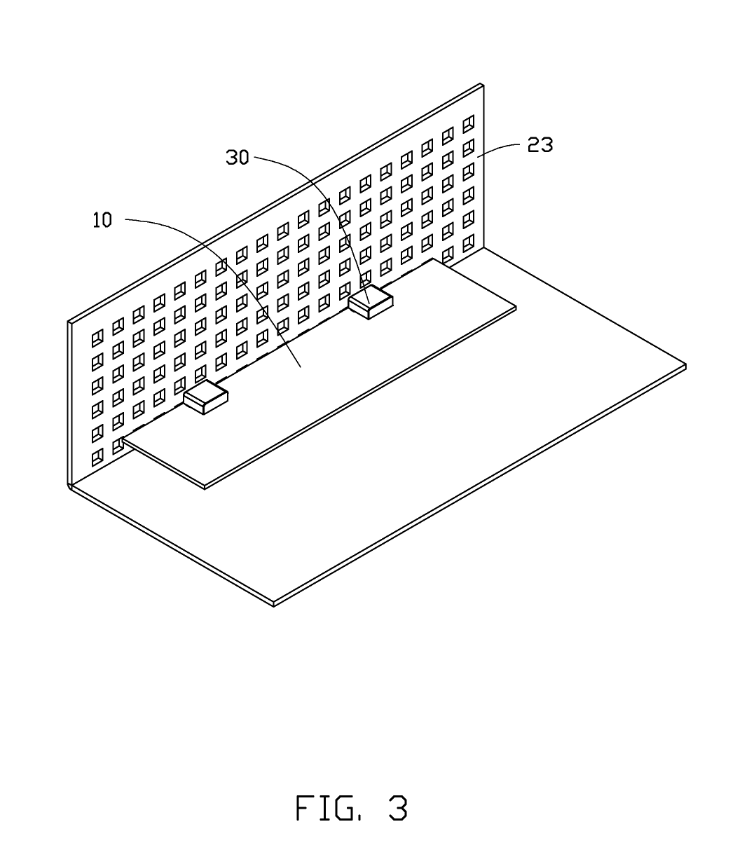

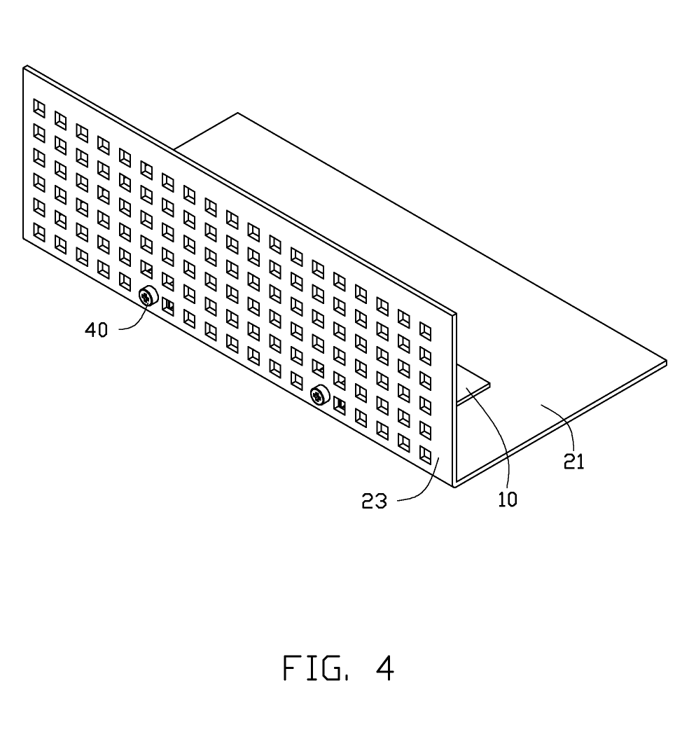

Referring to FIGS. 3 and 4, in assembly, the mounting members 30 are placed in front of the front side 11 of the circuit board 10, with the mounting members 30 respectively aligning with the slots 12. The mounting members 30 are moved backward, to allow the sidewalls 121 bounding each slot 12 to engage in the first recesses 34 of a corresponding one of the mounting members 30. The hooks 342 abut the corresponding sidewalls 121, to deform the corresponding resilient arms 341 inwardly. The mounting members 30 are further moved backward, until portions of the circuit board 10 bounding the rear ends of the slots 12 engage in the second recesses 36. The hooks 342 respectively align with the notches 123. The resilient arms 341 are restored to engage the hooks 342 in the corresponding notches 123. Thereby, the mounting members 30 are fixed to the front side 11 of the circuit board 10. The fixing holes 32 are parallel to the circuit board 10. The circuit board 10 is placed in the chassis 20, to allow the fixing holes 32 to respectively align with the holes 233. The screws 40 respectively extend through the holes 233 and engage in the corresponding fixing holes 32. Thereby, the circuit board 10 is perpendicularly mounted to the side plate 23.

Only two screws 40 need to be installed when mounting the circuit board 10, and the two screws 40 are installed from outside of the chassis 20, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A circuit board mounting apparatus, comprising:
a circuit board defining two slots in a front side of the circuit board;
a chassis comprising a side plate; and
two mounting members fixed to the side plate and respectively connected to the slots of the circuit board, wherein each of the mounting members comprises at least one hook locked to the circuit board, to perpendicularly fix the circuit board to the side plate.

2. The circuit board mounting apparatus of claim 1, wherein the circuit board forms two sidewalls bounding opposite sides of each slot, two first recesses are respectively defined in opposite sides of each mounting member, the sidewalls bounding each slot are engaged in the first recesses of a corresponding one of the mounting members.

3. The circuit board mounting apparatus of claim 2, wherein a notch is defined in each sidewall, a resilient arm slantingly extends forward and outward from each first recess, the number of the at least one hook of each mounting member is two, said two hooks of each mounting member respectively protrude from outer sides of the resilient arms of the mounting member, to respectively engage in the notches of the corresponding sidewalls.

4. The circuit board mounting apparatus of claim 3, wherein the notches are respectively defined in the sidewalls adjacent to front ends of the sidewalls, and the hooks are respectively formed on the resilient arms adjacent to front ends of the resilient arms.

5. The circuit board mounting apparatus of claim 2, wherein a second recess is defined in a rear end of each mounting member, with opposite ends of the second recess communicating with the first recesses of the mounting member, portions of the circuit board bounding rear ends of the slots respectively engage in the second recesses.

6. The circuit board mounting apparatus of claim 1, further comprising two fasteners, wherein the side plate of the chassis defines two spaced holes, a fixing hole parallel to the circuit board is defined in a front end of each mounting member, the fasteners extend through the holes of the side plate and engage in the fixing holes of the mounting members, to perpendicularly fix the circuit board to the side plate.
